(19) United States
(12) Patent Application Publication
(10) Pub. No.: US 2013/0187113 A1
(43) Pub. Date: Jul. 25, 2013

(54) Nonvolatile Memory Device Comprising a Metal-to-Insulator Transition Material

(71) Applicants: IMEC, Leuven (BE); Katholieke Universiteit Leuven, K.U. LEUVEN R&D, Leuven (BE)

(72) Inventors: Koen Martens, Leuven (BE); Iuliana Radu, Leuven (BE)

(73) Assignees: Katholieke Universiteit Leuven, K.U. LEUVEN R&D, Leuven (BE); IMEC, Leuven (BE)

(21) Appl. No.: 13/744,613

(22) Filed: Jan. 18, 2013

Related U.S. Application Data
(60) Provisional application No. 61/588,937, filed on Jan. 20, 2012.

(51) Int. Cl. H01L 45/00

(52) U.S. Cl. CPC H01L 45/1286
USPC 257/2

(57) ABSTRACT

A nonvolatile memory device is disclosed comprising a metal-to-insulator transition material thermally coupled to a Peltier element. During programming, a selected current is flowing through the Peltier element, the level thereof determining whether the temperature of the Peltier element and hence of the thermally coupled metal-to-insulator transition material decreases or increases. In response to this temperature change, the metal-to-insulator transition material will change from one electrical conduction phase to another. The memory device is read by applying current through the metal-to-insulator transition material, the current level being selected to maintain the phase of the metal-to-insulator transition material.

### CROSS REFERENCE TO RELATED APPLICATIONS

Pursuant to the provisions of 35 U.S.C. §119(e), this application claims priority to U.S. Provisional Patent Application Ser. No. 61/588,937, which was filed Jan. 20, 2012. The entire contents of U.S. Provisional Patent Application Ser. No. 61/588,937 are incorporated herein by reference.

### BACKGROUND

State-of-the-art memory technologies each have their limitations, some of which will be discussed in this paragraph. Flash memory is one of the slowest memories. Further CMOS scaling will lead to a very limited amount of electrons stored in the floating gate of the very small flash memory cells leading to, amongst others, retention problems. The typically embedded SRAM has its switching speed limited to nanosecond order of magnitudes in arrays, which is the fastest for memory arrays, but has a large cell area. DRAM becomes more and more difficult to scale, is denser but slower than SRAM and needs to be continuously refreshed. The currently upcoming RRAM has disadvantages such as the formation of a filament which leads to variability and reliability issues. The material transport needed for RRAM leads to irreversibility and limited cyclability or endurance. The upcoming STT MRAM typically requires large currents which results in large power dissipation. Although the switching speed of an STT MRAM is in the 10 nanoseconds range, its cell size is not as compact as flash memory cells and aggressive scalability of STT MRAM remains unproven.

Each of the existing memory types has its own particular limitations in terms of embeddability, energy/bit switch, speed, scalability, nonvolatility and reliability. Opportunities arise for a new type of memory device which provides improvements in one or more of these properties.

### SUMMARY

In one aspect, nonvolatile memory devices are disclosed comprising a Metal-to-Insulator Transition (MIT) element and a thermoelectric element thermally coupled to the MIT element. Preferably, the nonvolatile memory device comprises a metal-to-insulator transition material thermally coupled to a Peltier element. The MIT material and the thermoelectric element are positioned as to constitute a good thermal link between them, thereby obtaining efficient heating and cooling of the MIT material during programming while minimizing thermal leakage from the MIT element.

Such a memory device can be configured as a four terminal device, whereby the MIT element and the thermoelectric element have separate electrical terminals and both elements are only coupled thermally.

Such a memory device can be configured as a two terminal device, whereby the MIT element is incorporated in the thermoelectric element and both elements are thermally and electrically coupled.

Such a memory device can be configured as a three terminal device, whereby the MIT element is incorporated in the thermoelectric element and both elements are thermally and electrically coupled. One terminal is electrically connected to the MIT element, while the other two terminals are connected to different ends of the thermoelectric element.

Optionally, in either one of these memory devices, a barrier layer is inserted between the MIT element and one of its electrodes to tune the resistance of the MIT element.

In another aspect, methods are disclosed for operating a non-volatile memory device according to the previous aspect, the memory element comprising an MIT element and a thermoelectric element thermally coupled to the MIT element.

During programming, a selected current flows through the Peltier element, the level thereof determining whether the temperature of the Peltier element and hence of the thermally coupled metal-to-insulator transition material decreases or increases with respect to the steady state temperature. In response to this temporary and local temperature change, the metal-to-insulator transition material will change from one electrical conduction phase to another.

The memory device is read by applying a current through the metal-to-insulator transition material, the current level being selected to maintain the phase of the metal-to-insulator transition material.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

All drawings are intended to illustrate some aspects and embodiments of the present disclosure. The drawings described are only schematic and are non-limiting.

FIG. 1 shows a diagram of the resistance (R) versus temperature (T) characteristic of an MIT element indicating the off resistance (R_{off}), on resistance (Rₒₙ), and transition temperatures when cooling (T_{tH}) and when heating (T_{tL}).

FIGS. 2a-c shows general circuit representations of the Peltier-MIT memory in three different configurations according to this disclosure. Each configuration can be implemented in a memory array.

FIGS. 3a-e shows schematics of different configurations of the Peltier-MIT memory element according to this disclosure: a) 4-terminal, b) 2-terminal, c) 3-terminal with the MIT element also carrying the Peltier current, d) 3-terminal with a high conductive material carrying the Peltier current, e) 3 terminal having a barrier element between the MIT element and the thermally and electrically highly conductive junction material.

FIGS. 4a-c illustrates the write ‘1’ operation of a Peltier-MIT memory element according to this disclosure: a) state of memory element prior to the write operation, b) write operation by temporary and local heating of the MIT element with the Peltier element, c) state of the memory element after completion of the write operation.

FIGS. 5a-c illustrates of the write ‘0’ operation of a Peltier-MIT memory element according to this disclosure: a) state of memory element prior to the write operation, b) write operation by temporary and local cooling of the MIT element with the Peltier element, c) state of the memory element after completion of the write operation.

FIG. 6 illustrates the read operation of a Peltier-MIT memory element for which a low resistance sensing current is used which does not change the phase of the MIT material.

### DETAILED DESCRIPTION

In one aspect, non-volatile memory devices are disclosed comprising an MIT element (2) and a thermoelectric element (1) thermally coupled (3) to the MIT element (2). Preferably, this thermoelectric element (1) is a Peltier element.

A typical Metal-to-Insulator-Transition material (MIT) is VO₂. VO₂ shows a large change in its electronic structure and conductivity under the influence of external factors such as pressure or temperature. Sometimes the electronic change is associated with a small reversible shift in atomic lattice position thereby promising compatibility with sub-10 nm scalability.

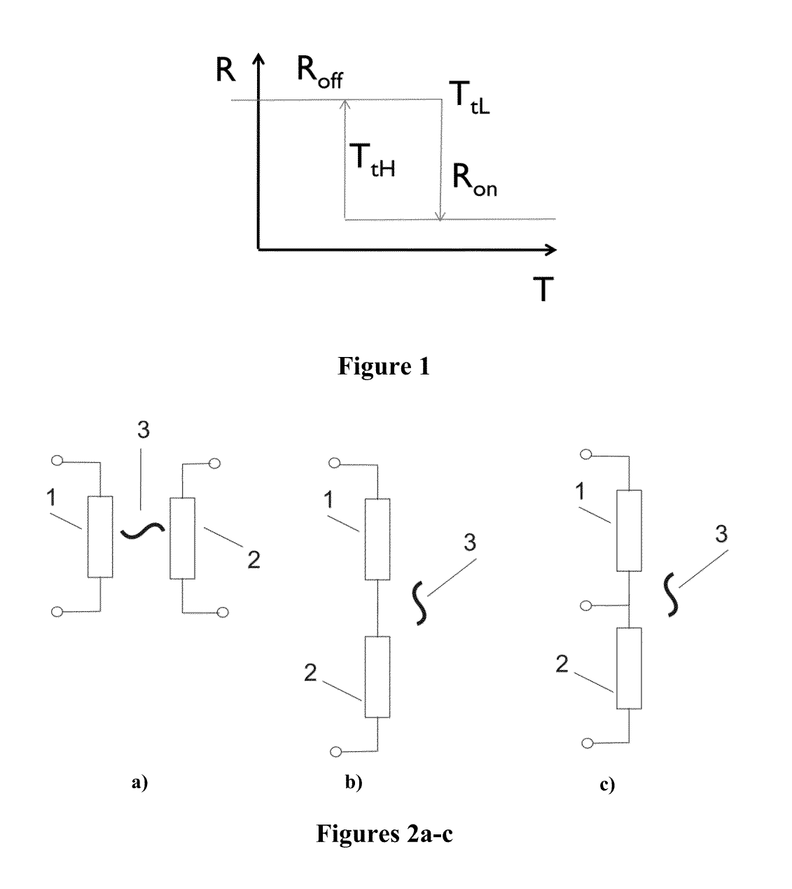

The MIT phase switches between a low electrical conductive state R_{off} and a high electrical conductive state Rₒₙ, as illustrated in FIG. 1, when heating (T_{tL}) or cooling (T_{tH}). This switching implies a bistable system which results in hysteresis behavior. Such a bistable system gives rise to a binary switch or memory.

A VO₂-based MIT memory element can change phase in 100 femtoseconds (fs), which approaches the theoretical minimal energy switch time limit of 40 fs and is near the transition time of 130 fs at the end of the roadmap as defined by the ITRS. The potential speed of a VO₂-based MIT memory element leapfrogs current DRAM, MRAM, PCM and NAND flash all having an switching speed above lns, and is of a similar magnitude as the switching speed of the 150-160 F² SRAM cells at the end of the roadmap as defined by the ITRS. These SRAM cells are considerably larger than an MIT memory element. F hereby refers the critical dimension obtainable in a given manufacturing technology. Based on a latent energy estimate, the switching energy for a VO₂-based MIT memory element having a volume of 5×5×5 nm³ is about 216 eV and about 13.8 eV for a volume of 2×2×2 nm³. This amount of switching energy is sufficiently large to obtain a good nonvolatile retention, is comparable to switching energies of logic devices being in the range of to 100 eV, and is much smaller than most switching energies of state-of-the-art MRAM, flash, PCM, RRAM and DRAM memory elements requiring>10⁴eV or more. Moreover, the absence of matter migration during operation of the MIT memory cell implies good reliability and the metallic on-state yields a high current drive.

The nonvolatile memory device comprises an element (2) containing an MIT (metal-to-insulator-transition) material, showing a first order phase transition at a given temperatures, the transition temperatures as illustrated in FIG. 1. The transition from one electrical conductive state to another electrical conductive state occurs when the temperature of the MIT material is changed. The MIT material has two relevant phases, which are here called the low and high temperature phase or the high R_{off} and low resistance Rₒₙ phase, respectively. An example of such an MIT material is vanadium dioxide or doped vanadium dioxide. Within the memory element, this MIT material is contained between two electrodes or terminals and constitutes a two-terminal temperature dependent resistor element, whose operation is schematically illustrated by FIG. 1. Optionally, a barrier layer can be added to this MIT element (2) to change properties such as the electrical or thermal resistance of the MIT element.

The nonvolatile memory device further comprises a thermoelectric element (1) which cools or heats when a current is running through it. The term “thermoelectric effect” refers to the direct conversion of a temperature difference to an electric voltage difference and vice-versa. When there is a different temperature between the terminals of a thermoelectric element (1), an electric voltage difference between these terminals is created. When an electrical voltage difference is applied between the terminals of the thermoelectric element (1), a temperature difference is created between these terminals. This effect is here used to change the temperature of objects which are thermally coupled to the thermoelectric element (1). Whether the thermoelectric element is heating or cooling, is determined by the polarity of the electric voltage applied over the thermoelectric element. Hence, thermoelectric elements are efficient temperature controllers. This thermoelectric effect is also referred to as the Peltier or Peltier-Seebeck effect. This thermoelectric element (1) can be made of a material such as BiTe, PbTe, SiGe, some silicides and so on of p-type and/or n-type nature or other thermoelectric materials or a combination thereof

Nonvolatile memory devices according to this disclosure thus comprises the combination of an MIT element (2) and at least one thermoelectric element (1) thermally coupled (3) to the MIT element (2), such that by running a current through the at least one thermoelectric element (1), the MIT element (2) is respectively cooled or heated whereby the temperature change of the MIT material is sufficient to change the phase of the MIT material to the high or low temperature phase depending on whether heating or cooling respectively. This occurs irrespective of the initial steady state temperature T_{IC} of the MIT material within the operating temperature range specified for the chip. The better the thermal link (3) between the thermoelectric element (1) and the MIT element (2), the more efficient the MIT material of the MIT element (2) will be cooled and/or heated by the thermoelectric element (1). Also, the thermal energy lost through conduction away from the MIT element (2) is minimized.

Some of the possible configurations of the nonvolatile memory device comprising the thermoelectric (1) and MIT (2) elements are shown in FIGS. 2a-c.

FIG. 2a shows a nonvolatile memory device comprising an MIT element (2) and a thermoelectric element (1) only coupled thermally (3) to the MIT element (1). The electrical current flowing through the MIT element (2) is not flowing through the thermoelectric element (1). The temperature control of the MIT element (2) by the thermoelectric element (1) only depends on the current run between the two terminals of the thermoelectric element (1).

FIG. 2b shows another nonvolatile memory device comprising an MIT element (2) and a thermoelectric element (1) thermally coupled (3) to the MIT element (2). Here one terminal of the MIT element (2) is only electrically connected to one terminal of the thermoelectric element (1) such that the electric current flowing through the MIT element (2) flows through the thermoelectric element (1).

FIG. 2c shows another nonvolatile memory device comprising an MIT element (2) and a thermoelectric element (1) thermally coupled (3) to the MIT element (1). Here one terminal of the MIT element (2) is also electrically connected to one terminal of the thermoelectric element (1) such that the electric current flowing through the MIT element (2) at least partially, optionally completely, flows through the thermoelectric element (1). The terminal common between the MIT element (2) and the thermoelectric element (1) is an outer terminal of the nonvolatile memory device such that an external voltage bias can be applied to this common terminal.

The memory is at a steady state temperature T_{IC}, which is within the operating temperature range defined for the integrated circuit. The operating temperature range falls within the bistable temperature range of the MIT element. The bistable temperature range is the temperature range in which both phases Rₒₙ and R_{off} of the MIT material of the MIT element (2) are stable. Sufficiently far outside of this bistable range either the high Rₒₙ (temperature higher than the bistable temperature range) or the low R_{off} (temperature lower than the bistable temperature range) phase is dominant.

The thermoelectric element (1) is capable of varying, i.e., heating or cooling, the temperature T_{MIT} of the MIT element (2) outside of this bistable range to convert the MIT material of the MIT element (2) to the desired phase. So the thermoelectric element (1) is used to locally induce temporary temperature excursions of temperature T_{MIT} of the MIT material element (2) from the temperature T_{IC} of the integrated circuit to either switch the MIT material to the high Rₒₙ or low R_{off} temperature state. After the application of the heating or cooling pulse to the MIT element (2), the temperature T_{MIT} returns to the chip temperature T_{IC}, but the phase induced by the temperature pulse remains. Since the MIT material is bistable in the operating temperature range and both the high and low temperature state are stable for long times, the combination of an MIT element (2) and at least one thermoelectric element (1) thermally coupled (3) to the MIT element (2) functions as a nonvolatile memory. Since the switching occurs within the volume of the MIT material high scalability of the nonvolatile memory is expected. The operating temperature range can be non-standard, e.g., for human implant applications near 37° C. Reading of the nonvolatile memory element is done by sensing the resistance of the MIT element (2) without bringing the MIT material outside of its bistable temperature range.

The operating temperature range of the memory can be enlarged by increasing the bistable temperature range by engineering the MIT material.

### EXAMPLES

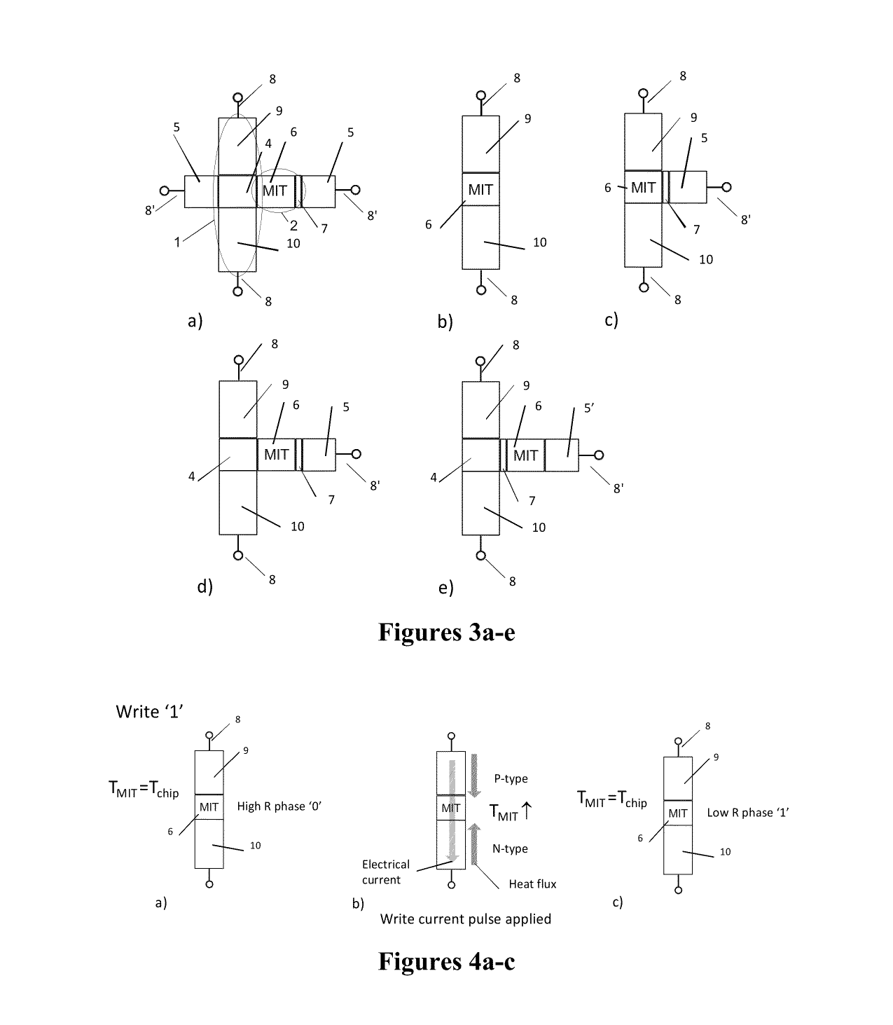

Some implementations of the thermoelectric-MIT nonvolatile memory device according to this disclosure are shown schematically in FIGS. 3a-e.

The implementation in FIG. 3a is a four-terminal device. A p-type Peltier material (9) and an n-type Peltier material (10) such as SiGe, Bi₂Te₃, CoSb₃, and so on and a junction conductor (4) form the Peltier element (1). The junction conductor (4) has a low electrical and thermal resistance and conveys the temperature of the thermoelectric element (2) to the MIT element (1). The MIT element (2) is thermally connected to the junction conductor (4) and electrically to an interconnect conductor (5) with a low thermal conductivity such as Ti, TiN, GeSbTe. Optionally, a barrier material (7) is present between the MIT element (2) and the interconnect conductor (5) to tune the overall resistance of the MIT element (1). During the read operation, electrical current passes through the interconnect conductor (5) terminals and during the write operation electrical current passes through the Peltier material (9, 10) terminals (8).

This four-terminal configuration prevents the Peltier current passing through the MIT material to avoid additional Joule heating of the MIT material. The low electrical and thermal resistance junction conductor (4) ensures a good thermal link between the MIT element (2) and Peltier element (1). The combination of MIT element (2) and the at least one Peltier element (1) is embedded in an electrically and thermally insulating material such as SiO₂, Si₃N₄, air, vacuum to avoid heat dissipation to the environment.

The implementation of FIG. 3b is a two-terminal device. The MIT material is sandwiched in between the n-type (10) and p-type (9) Peltier materials. The heating, cooling and reading is obtained by running a current between the terminals (8) of the Peltier element (1), the magnitude of the current will determine the temperature of the Peltier element (1) and of the MIT element (2) in between and hence whether the MIT material is read or programmed. This approach allows to reduce the thermal dissipation to the environment because of the reduced amount of interconnects. One has to take into account the Joule heating occurring in the MIT element (2) when cooling as the MIT element (2) also carries the current of the Peltier (1) element.

The implementation of FIG. 3c is a three-terminal device. A tunnel barrier (7) is added in between the MIT element (2) and the interconnect conductor (5) to tune the readout resistance of the MIT element (1). Heating and cooling occurs through the Peltier terminals (8) and reading occurs between one of the Peltier terminals (8) and the interconnect (5) terminal (8′).

The implementation of FIG. 3d is a three-terminal device. It is a modification of the implementation of FIG. 3c, further including a junction conductor (4) with low thermal and electrical resistivity in between the n-type (10) and p-type (9) materials of the Peltier element (1). This junction conductor (4) prevents the current of the Peltier element (2) from flowing through the MIT element (2), thereby avoiding the Joule heating in the MIT element (2) during programming. Instead of being inserted between the MIT element (2) and the interconnect conductor (5), the optional barrier (7) can be placed in between the junction conductor (4) and the MIT element (2) as shown in FIG. 3e.

The implementation of FIG. 3e is a three-terminal device. It is a modification of the implementation of FIG. 3d. Instead of inserting the optional barrier (7) between the MIT element (2) and the interconnect conductor (5′), the optional barrier (7) is placed in between the junction conductor (4) and the MIT element (2).

In another aspect, methods are disclosed for operating a non-volatile memory element according to the previous aspect, the memory element comprising an MIT element (2) and a thermoelectric element (1) thermally coupled to the MIT element (2). Preferably, this thermoelectric element (1) is a Peltier element.

The writing of a ‘1’, i.e., switch to the low resistance state Rₒₙ, of nonvolatile memory devices according to this disclosure is illustrated in FIGS. 4a-c for a two-terminal memory device. The nonvolatile memory device is initially in the high resistance phase R_{off} as shown in FIG. 4a with the MIT element (2) temperature T_{MIT} being the same as the chip temperature T_{IC}. The integrated circuit temperature is within the bistable ranges and both phases are stable. In FIG. 4b the write operation is shown. Temporarily and locally, the temperature T_{MIT} of the MIT element (2) is raised out of the bistable temperature range by running a current through the Peltier element. The corresponding temperature pulse converts the phase of the MIT material to the low resistance, high temperature phase as shown in FIG. 4c. After the current pulse is applied, the temperature T_{MIT} of the MIT element drops back to the chip temperature T_{IC}.

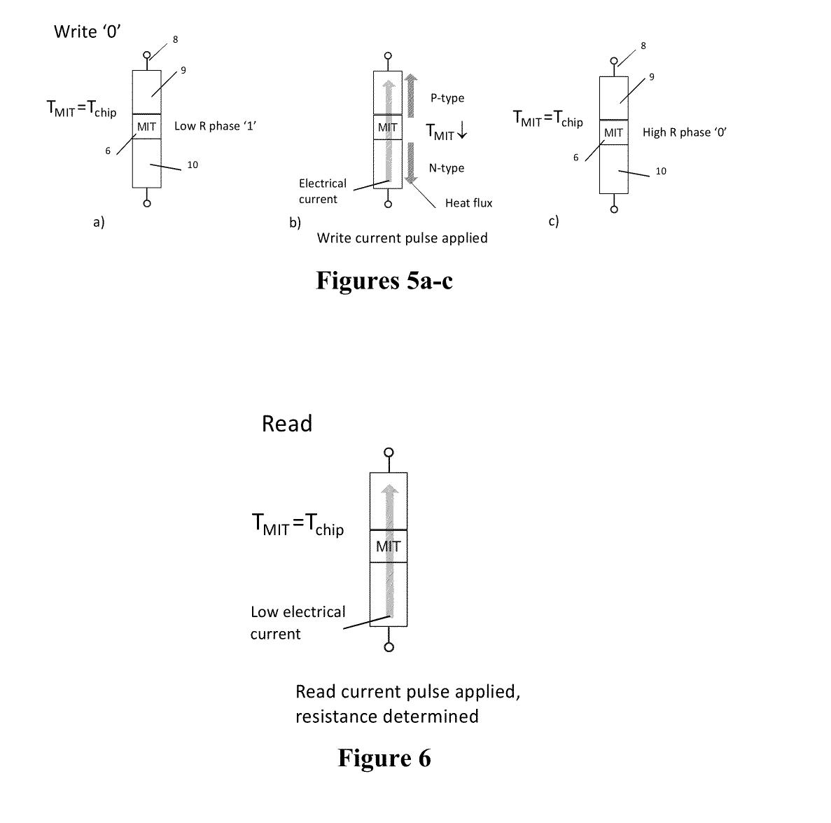

The writing of a ‘0’, i.e., switch to high resistance state Rₒₙ, of nonvolatile memory devices according to this disclosure is illustrated in FIGS. 5a-c for a two-terminal memory device. The nonvolatile memory device is initially in the low resistance phase as shown in FIG. 5a with the MIT element temperature T_{MIT} being the same as the chip temperature T_{IC}. In FIG. 5b the write operation is shown. Temporarily and locally, the temperature T_{MIT} of the MIT element (2) is lowered out of the bistable temperature range by running a current through the Peltier element in the inverse direction as the ‘1’ writing operation. The corresponding temperature pulse converts the phase of the MIT material to the high resistance, low temperature phase as shown in FIG. 5c. This phase remains when the device temperature T_{MIT} reverts back to the chip temperature T_{IC}.

The read operation of nonvolatile memory devices according to this disclosure is illustrated in FIG. 6 by means of a two-terminal memory device. A low current is used to read out the resistance of the MIT element (2). The current level of this read-out current is selected to maintain the MIT element (2) temperature T_{MIT} within the bistable temperature range.

It is intended that the foregoing detailed description be regarded as illustrative rather than limiting and that it is understood that the following claims including all equivalents are intended to define the scope of the invention. The claims should not be read as limited to the described order or elements unless stated to that effect. Therefore, all embodiments that come within the scope and spirit of the following claims and equivalents thereto are claimed as the invention.

1. A device, comprising:
a Metal-to-Insulator Transition (MIT) element; and
a thermoelectric element thermally coupled to the MIT element.
